(19) United States
(12) Patent Application Publication
(10) Pub. No.: US 2019/0304794 A1
(43) Pub. Date: Oct. 3, 2019

(54) METHOD FOR ETCHING SHAPES INTO SILICON

(71) Applicant: Innovative Micro Technology, Goleta, CA (US)

(72) Inventors: Tao Gilbert, Goleta, CA (US); Sangwoo Kim, Santa Barbara, CA (US)

(73) Assignee: Innovative Micro Technology, Goleta, CA (US)

(21) Appl. No.: 16/369,140

(22) Filed: Mar. 29, 2019

Related U.S. Application Data
(60) Provisional application No. 62/649,692, filed on Mar. 29, 2018.

(51) Int. Cl. H01L 21/308; H01L 33/58; H01L 31/0232

(52) U.S. Cl. CPC H01L 21/3085; H01L 2933/0058; H01L 31/02325; H01L 33/58

(57) ABSTRACT

The method described here uses gray scale lithography to form curve surfaces in photoresist. These surfaces can be of arbitrary shape since the remaining resist following exposure and develop is dependent on the exposure dose, which is controlled precisely by the opacity of the photo-mask. The process may include a silicon etch step, followed by a photoresist etch step to form an etching cycle. Each etch cycle may form a pair of substantially orthogonal stepped surfaces, with a characteristic “rise” and “run.”

### CROSS REFERENCE TO RELATED APPLICATIONS

This application claims priority to U.S. Provisional Application Ser. No. 62/649,692, filed Mar. 29, 2018 and incorporated by reference in its entirety.

### STATEMENT REGARDING FEDERALLY SPONSORED RESEARCH

Not applicable.

### STATEMENT REGARDING MICROFICHE APPENDIX

Not applicable.

### BACKGROUND

This invention relates to integrated circuit and microelectromechanical systems (MEMS) devices. More particularly, this invention relates to a method for forming complex shapes in a silicon substrate.

Microelectromechanical systems (MEMS) are very small moveable structures made on a substrate using lithographic processing techniques, such as those used to manufacture semiconductor devices. MEMS devices may be moveable actuators, sensors, valves, pistons, or switches, for example, with characteristic dimensions of a few microns to hundreds of microns. One example of a MEMS device is a microfabricated cantilevered beam, which may be used to switch electrical signals. Because of its small size and fragile structure, the movable cantilever may be enclosed in a cavity to protect it and to allow its operation in an evacuated environment. Therefore, upon fabrication of the moveable structure on a wafer, (device wafer) the device wafer may be mated with a lid wafer, in which depressions have been formed to allow clearance for the structure and its movement. To maintain the vacuum over the lifetime of the device, a getter material may also be enclosed in the device cavity upon sealing the lid wafer against the device wafer.

Many MEMS devices may make use of complex shapes in their design. Actuators, such as that mentioned above for example, may come in a wide variety of shapes and size and throw. Optical light shaping elements may also make use of complex refractive surfaces to produce the desired optical performance. However, most lithographic processes are planar by nature, wherein photoresist is exposed through a mask, such that the two-dimensional, planar design is imparted to the surface.

Forming shapes in the dimension orthogonal to this plane is generally not possible.

However, for optics applications, curved surfaces may be required for beam forming. Because the current art cannot create curved surfaces, optical components such as lenses and parabolic mirrors must be assembled as discrete onto an optical platform. Placement precision of these discrete components generally requires a computerized pick-and-place robot. Furthermore discrete lenses are generally spheres, which have large diameter tolerances and cannot be corrected for aberrations. These discrete lenses are difficult to cascade, which is the typical remedy to correct aberrations in macroscopic lens systems.

Discrete lenses of diameters <1 mm are commercially available, although not below 0.25 mm. Assembly of these elements is costly, slow, and requires active alignment.

Accordingly, the formation of complex, three-dimensional shapes in a semiconductor substrate has posed an unresolved problem. What is needed is a means by which precisely controlled curved surfaces can be directly etched into substrates.

### SUMMARY

A method is described which can form complex, three dimensional shapes in a silicon substrate. Applications of the novel method include optical elements such as lenses, reflective and refractive surfaces.

The method described here uses gray scale lithography to form curved surfaces in photoresist. These surfaces can be of arbitrary shape since the remaining resist following exposure and develop is dependent on the exposure dose, which is controlled precisely by the opacity of the photo-mask. Disclosed here is a method in which the shape of the curved resist is transferred into the silicon.

The method uses the mechanics of a DRIE to create surfaces of arbitrary shape. Central to this method is the concept that a curved surface may be approximated by a plurality of small discrete steps, wherein each step comprises a pair of orthogonal surfaces, a vertical surface and a horizontal surface.

To form a step in the surface of a semiconductor substrate, a silicon etch using SF6 and DRIE, for example, may be conducted. The surface of the silicon may thereby be etched for a first period. This silicon etch may form a step on the surface of the silicon. The working gas SF6 is then exhausted from the chamber and replaced with oxygen. The oxygen is then used to etch the photoresist. The photoresist may be etched for a second period, reducing the area on the silicon which is covered by photoresist. The duration of the photoresist etch may remove deeper portions of the photoresist material and expose a new area of the silicon surface. Accordingly, this duration may determine the lateral dimensions of the remaining photoresist, and thus the “run” of the subsequent step. Another silicon etch may then be performed on the newly exposed silicon surface, by replacing the oxygen O₂ in the chamber with SF6.

A single silicon etch, followed by a photoresist etch, defines a single etch cycle and thereby forms a single step on the surface of the silicon substrate. As described, the step may comprise two orthogonal surfaces, the step having a rise and a run. The rise may be determined by the duration, and thus the depth, of the silicon etch. The run may be determined by the duration of the photoresist etch. Accordingly, the ratio of the photoresist/DRIE etch times may determine the instantaneous slope of the resulting contour, on average.

A plurality of etch cycles may form a plurality of discrete, substantially orthogonal stepped surfaces, wherein in the curved contour is defined by a continuous line intersecting the discrete, stepped surfaces. The slope of this contour may be continuously varying throughout the process. Accordingly, as in the theory of calculus, when the step size is sufficiently small, the discrete nature of the steps may disappear and for a smooth, continuous contour. Even for rather large step sizes, the steps may be smaller than the wavelength of light, such that the radiation does not interact with the discrete steps. Instead, the contour defined by a continuous line intersecting the discrete, stepped surfaces may operate as a lens, shaping the beam of light transmitted, refracted, or reflected from its surfaces.

These and other features and advantages are described in, or are apparent from, the following detailed description.

### BRIEF DESCRIPTION OF THE DRAWINGS

Various exemplary details are described with reference to the following figures, wherein:

FIG. 1 is a schematic, step-wise illustration of the formation of a complex shape in silicon using this method having a particular ratio of silicon etching to photoresist etching;

FIG. 2 is a schematic, step-wise illustration of the formation of a complex shape in silicon using this method having a particular ratio of silicon etching to photoresist etching, wherein the ratio of silicon etching to photoresist etching is somewhat smaller than in FIG. 1;

FIG. 3 is a schematic, step-wise illustration of the formation of a complex shape in silicon using this method having a particular ratio of silicon etching to photoresist etching, wherein the ratio of silicon etching to photoresist etching is somewhat smaller than in FIG. 2;

FIG. 4 is a schematic, step-wise illustration of the formation of a complex shape in silicon using this method having a particular ratio of silicon etching to photoresist etching, wherein the ratio of silicon etching to photoresist etching is somewhat smaller than in FIG. 3; and

FIG. 5a-5f are schematic, cross sectional illustrations showing steps of a method for making complex shapes in silicon.

### DETAILED DESCRIPTION

The art of etching micron-sized features into silicon has advanced very rapidly in the last 50 years due to the research and development that has been focused on this by the semiconducting industry. The rapid development in the last 10 years has been no less dramatic, owing to investments made by the MEMS industry. In both cases however, the etching profiles that have been created are rectilinear. This results in structures, such as transistors and interconnect wiring that can be maximally packed into the smallest area on a wafer.

Dry etching of Si is generally carried out in a plasma containing SF6. A common etch used by the MEMS industry is one employing SF6 for 3-6 second. Then within a few 10's of milliseconds the gas is switched to CF4 or C4F8 without extinguishing the plasma. This chemistry deposits a Teflon-like polymer on the walls of the Si features, but it does not etch the Si. The duration of the polymer deposition cycle is also 3-6 seconds. This etch/deposition cycle is repeated many times resulting in a deep etch that can extend through the entire thickness of a Si wafer (500 um). The side walls of the etch features are very close to 90 degrees with respect to the surface of the wafer—thus a very rectilinear topography results. The gas pumping and valving equipment that enable the rapid toggling of the plasma chemistry is common in MEMS foundries and is referred to DRIE (for Deep Reactive Ion Etcher) and this modulated chemistry process is often referred to as the Bosch process, after the company where it was first developed.

The characteristics of the etched Si created by the Bosch process are the antithesis of those needed for curved lenses.

Optical elements may also be made in silicon substrates using photolithographic processing techniques. In particular, the etching of curved surfaces into Si has been demonstrated, using a patterned photoresist disk that is heated to the softening point of the resist, where surface tension pulls it into the shape of a spherical segment. Often the shape error of such a process is unacceptable and is dependent on age and relative hydration of the resist. In cases where the shape error is of the curved resist template is acceptable, the relative erosion rate of the resist compared to the etch rate of the Si determines the final curvature of the resulting Si lens. This greatly restricts the type of resist and the method of etch, as well as the surface quality (roughness) of the final product.

The systems and methods described herein may be particularly applicable to microfabricated optical tables, wherein small optical devices are formed on a substrate surface and enclosed with a lid wafer. The optical devices may include light sources such as light emitting diodes (LED's), beam shaping structures such as lenses and turning mirrors, and modulation devices such as Faraday rotators and optical isolators. After fabrication, these devices may be enclosed with a lid wafer to protect them in an encapsulated device cavity. Some devices, such as optical detectors and optical or laser emitters, may require a vacuum environment, such that the device cavity may need to be hermetically sealed. Such optical units may be made even smaller and more cheaply if the optical elements are formed integrally to the silicon substrate, that is, wherein the optical element is formed in and from the material of the substrate itself, rather than as a separate component that must be placed precisely inside the optical package.

The systems and methods described herein may be applied to components manufactured on a silicon substrate, that have complex, three-dimensional shapes, and include optical systems such as those mentioned above.

The method described here uses gray scale lithography to form curve surfaces in photoresist. These surfaces can be of arbitrary shape since the remaining resist following exposure and develop is dependent on the exposure dose, which is controlled precisely by the opacity of the photo-mask. Using this method, the shape of the curved resist is transferred into the silicon.

Disclosed here is a method that uses the mechanics of a DRIE to create surfaces of arbitrary shape.

Arbitrary shapes can be formed in photoresist by gray scale lithography of resist reflow. Gray scale provides far more flexibility in the resulting shapes that can be formed, because resist reflow is constrained to surfaces of lowest energy, which result from the action of surface tension in softened resist. Gray scale lithography is therefore preferred. Using these arbitrary shapes that are formed in resist the method disclosed here is to etch the Si wafers that have been patterned with resist in the following process:

1) Etch exposed Si in an SF6 plasma for x seconds

2) Etch exposed photoresist in an O₂ plasma for y seconds

3) Repeat until the photoresist is consumed.

Silicon deep reactive ion etching is generally done in an environment containing mostly SF6 gas with a smaller amount of oxygen O₂. In one embodiment, the proportion of SF6 to O₂ is at a ratio of about 0.1% to 95%. Workable gas pressures are in the range 3 mT-60 mT, and more preferably about 15 mT.

For a known etch rate of Si in SF6 and a known etch rate of resist in O₂ in a well characterized environment, the values of x and y can easily be chosen. If it is desired to create a surface in the Si that is identical to that in the original resist, the etch depth per cycle of the Si must equal the etch depth per cycle of the resist. If another shape such as a shallower (or steeper) step is desired, then the values of the photoresist duration relative to the silicon etch duration are changed accordingly. Generally a steep step results from a long silicon etch versus photoresist etch, whereas a shallower step results from a shorter silicon etch versus photoresist etch. In one exemplary embodiment, x=y=3 seconds.

If however a Si surface desired that similar to that of the resist, but has greater or lesser final height, then the relative etch depth per cycle of the SF6 and O₂ periods can be adjusted accordingly.

Accordingly, to form a step in the surface of a semiconductor substrate, a silicon etch using SF6 and DRIE, for example, may be conducted. The surface of the silicon may thereby be etched for about 3 seconds. This silicon etch may form a step on the surface of the silicon. The working gas SF6 is then exhausted from the chamber and replaced with oxygen, O₂. The oxygen O₂ is then used to etch the photoresist. The photoresist may be etched for another 3 seconds, reducing the area on the silicon which is covered by photoresist. Another silicon etch may then be performed by replacing the oxygen in the chamber with SF6.

A single silicon etch, followed by a photoresist etch, defines a single etch cycle and thereby forms a single step on the surface of the silicon substrate. The step may comprise two orthogonal surfaces, the step having a rise and the run. The rise may be determined by the duration, and thus the depth, of the silicon etch. The run may be determined by the duration of the photoresist etch. A plurality of etch cycles may form a plurality of discrete, substantially orthogonal stepped surfaces. Using these features, a curved contour may be defined by a continuous line intersecting the discrete, stepped surfaces. Accordingly, as in the theory of calculus, when the step size is sufficiently small, the discrete nature of the steps may disappear and the structure may act like a smooth, continuous contour. Even for rather large step sizes, the steps may be smaller than the wavelength of light, such that the radiation does not interact with the discrete steps. Instead, the contour defined by a continuous line intersecting the discrete, stepped surfaces may operate as a lens, shaping the beam of light transmitted, refracted, or reflected from its surfaces.

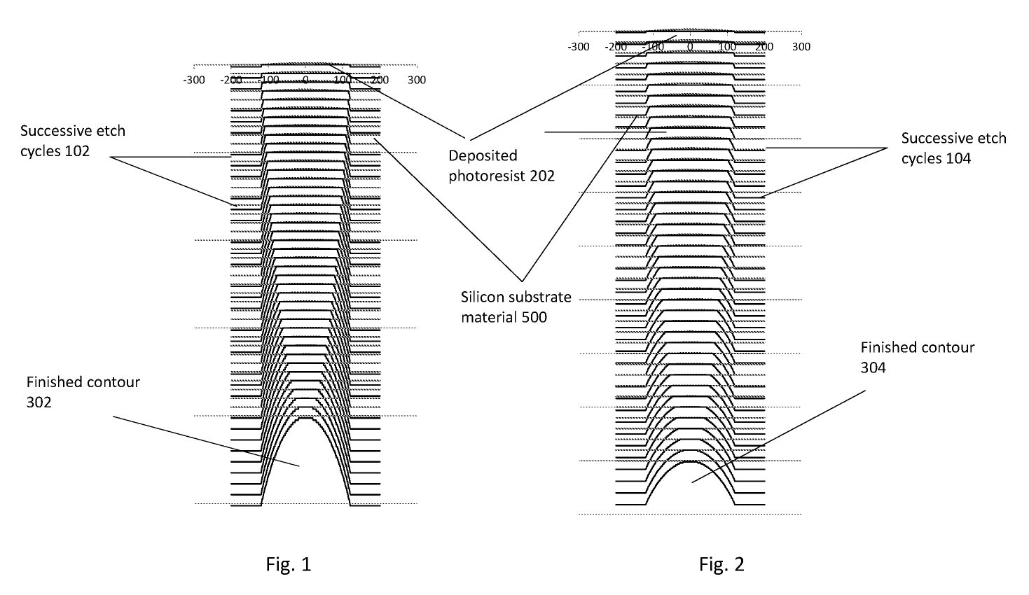

FIG. 1 is a schematic, step-wise illustration of the formation of a complex shape in silicon using this method having a particular ratio of silicon etching to photoresist etching. Each of the successive lines in the vertical direction illustrates a successive etching cycle. Each etching cycle results in the formation of a stepped surface. As mentioned previously, the stepped surface, as the term is used here, refers to a pair of orthogonal planes, such as one vertical plane and one horizontal plane. For consistency with mathematical terminology, the vertical plane may be referred to the “rise” of the step, and the horizontal plane may be referred to as the “run” of the step. The ratio of rise to run defines the slope that will be imparted to the contour, wherein the contour of the complex shape is defined by a continuous line intersecting the discrete, stepped surfaces. The ratio of rise to run in FIG. 1 may be about 10.

In the first horizontal line in FIG. 1, no lithographic processing has occurred, and the photoresist 202 is shown disposed on the surface of the silicon substrate 500. A silicon etch is performed, resulting in the step shown in the second horizontal line. The photoresist 202 is then etched in an oxygen plasma, followed by another silicon etch, resulting in the second step shown in the fourth line of FIG. 1.

Subsequent horizontal lines illustrate subsequent etch cycles 102 (one silicon etch followed by one photoresist etch). The process ends with the lowermost horizontal line 300 showing the formation of the complex contour 302.

FIG. 2 is a schematic, step-wise illustration of the formation of a complex shape in silicon using this method having a particular ratio of silicon etching to photoresist etching, wherein the ratio of photoresist etching to silicon etching is somewhat larger than in FIG. 1. The photoresist 202 is shown disposed on the surface of the silicon substrate 500. Because more photoresist is etched, the ratio of rise to run is lowered. The ratio of rise to run in FIG. 2 may be about 2.

Subsequent horizontal lines illustrate subsequent etch cycles 104 (one silicon etch followed by one photoresist etch). The process ends with the lowermost horizontal line 300 showing the formation of the complex contour 304.

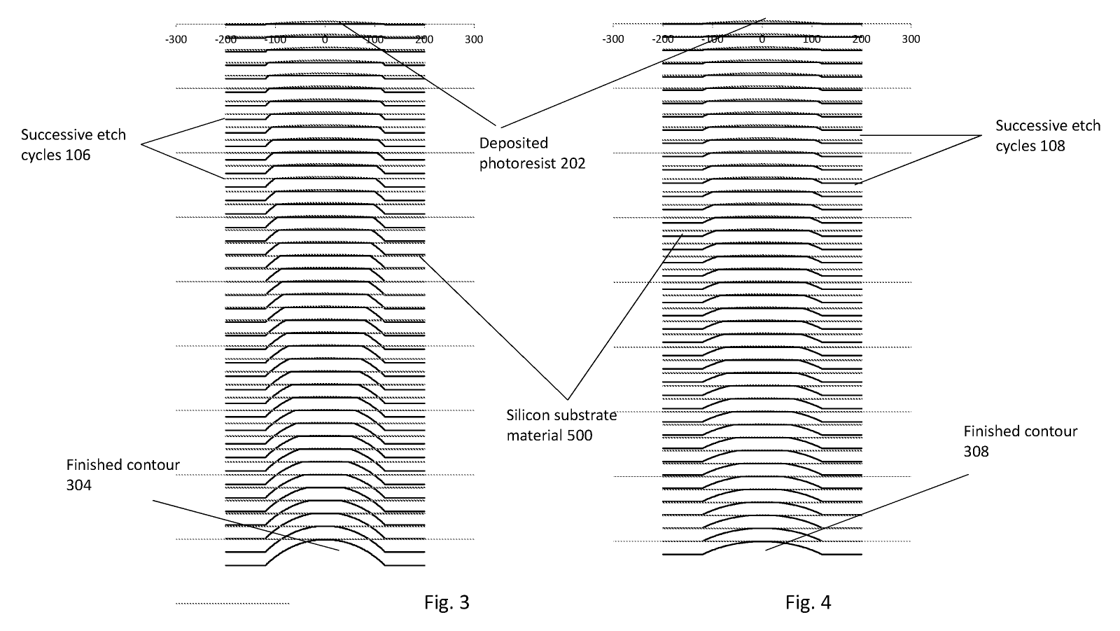

FIG. 3 is a schematic, step-wise illustration of the formation of a complex shape in silicon using this method having a particular ratio of silicon etching to photoresist etching, wherein the ratio of photoresist etching to silicon etching is somewhat larger than in FIG. 2. The photoresist 202 is shown disposed on the surface of the silicon substrate 500. Because more photoresist is etched, the ratio of rise to run is lowered. The ratio of rise to run in FIG. 2 may be about 0.5.

Subsequent horizontal lines illustrate subsequent etch cycles 106 (one silicon etch followed by one photoresist etch). The process ends with the lowermost horizontal line 300 showing the formation of the complex contour 306.

FIG. 4 is a schematic, step-wise illustration of the formation of a complex shape in silicon using this method having a particular ratio of silicon etching to photoresist etching, wherein the ratio of photoresist etching to silicon etching is somewhat larger than in FIG. 3. The photoresist 202 is shown disposed on the surface of the silicon substrate 500. Because more photoresist is etched, the ratio of rise to run is lowered. The ratio of rise to run in FIG. 4 may be about 0.1.

Subsequent horizontal lines illustrate subsequent etch cycles 108 (one silicon etch followed by one photoresist etch). The process ends with the lowermost horizontal line 300 showing the formation of the complex contour 308.

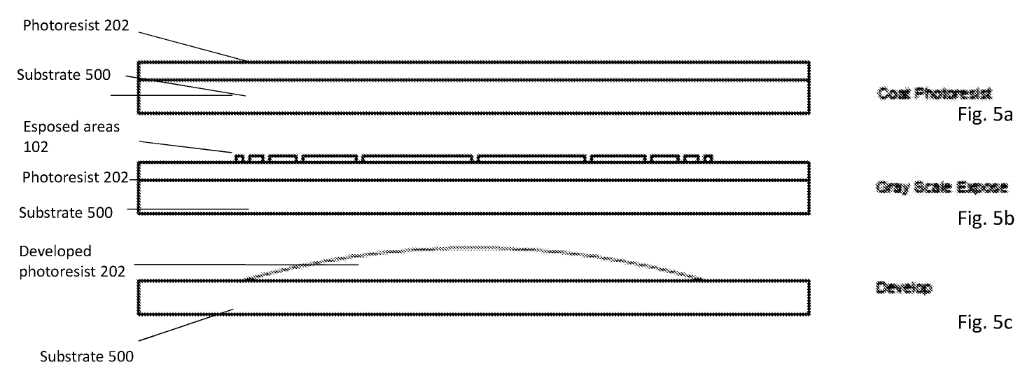

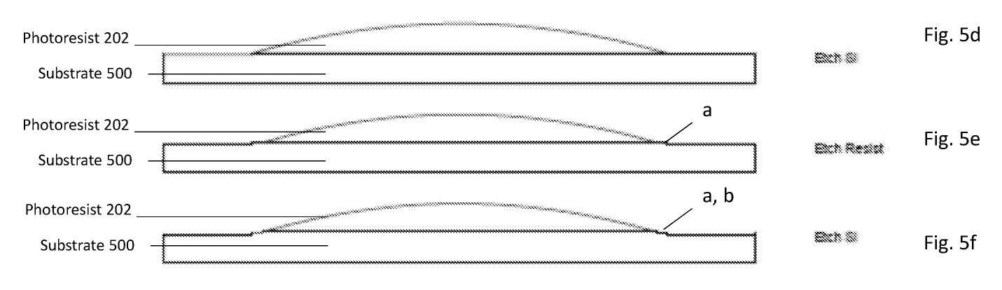

FIG. 5a-5f are schematic, cross sectional illustrations showing steps of a method for making complex shapes in silicon at successive points in time. FIG. 5a shows the bare silicon substrate with a layer of photoresist 202 applied to the top of the substrate 500.

FIG. 5b is a schematic, cross sectional illustration showing the exposure pattern of the resist, by illumination through a mask 102. The mask features 102 shown in FIG. 5b may be subwavelength, such that the light does not interfere directly with the edges of the mask 102, but rather may diffract around the features as through a slit. This exposure pattern may result in the complex, contoured photoresist surface 202 shown in FIG. 5c.

FIG. 5c is a schematic, cross sectional illustration showing the illuminated photoresist after development, that is, after the removal of the illuminated portions (or shaded portions in the case of a negative photoresist). Because of the shape of the photoresist layer, the photoresist may be underexposed in some areas and over exposed in others. This may result in the photoresist obtaining a round shape as shown in FIG. 5c.

FIG. 5d is a schematic, cross sectional illustration showing the silicon substrate 500 and the photoresist at the beginning of an single etch cycle. The condition of the silicon 500 and photoresist 202 are largely as they were previously in FIG. 5c.

FIG. 5e is a schematic, cross sectional illustration showing the condition of the silicon substrate 500 and the photoresist 202 after the first etch cycle. A step “a” is formed in the silicon substrate from the DRIE etch step, having two stepped orthogonal surfaces comprising a rise and a run, wherein the rise is orthogonal to the run. The photoresist has also been etched in FIG. 5e, to form the run of the subsequent step. In FIG. 5e, the rise is substantially twice the lateral distance of the run.

FIG. 5f is a schematic, cross sectional illustration showing the condition of the silicon substrate 500 and the photoresist 202 after the second etch cycle. A second step “b” is formed in the silicon substrate from the DRIE etch step, such that now there are two steps, each having two orthogonal surfaces comprising a rise and a run, wherein the rise is orthogonal to the run. The photoresist has also been etched a second time in FIG. 5f, to form the run of a subsequent (third) step. In FIG. 5f, the rise is substantially twice the lateral distance of the run.

The process illustrated in FIGS. 5a-5f may be repeated until the desired contour is reached. The total process may be as was illustrated in FIGS. 1-4.

Accordingly, a contour formed in a semiconductor substrate is disclosed. The contour may be a raised feature with a curved contour, wherein the curved contour comprises multiple discrete, substantially orthogonal stepped surfaces, wherein in the curved contour is defined by a continuous line intersecting the discrete, stepped surfaces. Each stepped orthogonal surface comprises a rise and a run, wherein the rise is orthogonal to the run, and wherein the rise is substantially equal to the run. Alternatively, each stepped orthogonal surface may comprise a rise and a run, wherein the rise is orthogonal to the run, and wherein the rise is substantially twice the run. Alternatively, each stepped orthogonal surface may comprise a rise and a run, wherein the rise is orthogonal to the run, and wherein the rise is substantially twice the run. Alternatively, the ratio of rise to run may vary across the contour from about 0.1 to about 10. Each stepped orthogonal surface may have a lateral extent less than about 100 microns.

The contour formed in the semiconductor surface may define an optical refractive or reflective beam shaping element. The beam shaping element may be a lens with a focal distance of less than about 1 micron. The microfabricated contour may form a portion of an optical device, which further includes an optical source emitting a beam of radiation; and the mircofrabicated contour, wherein the microfabricated contour shapes the beam of radiation by refraction or reflection at the contour.

A process is also disclosed. The process may include depositing a layer of photoresist on the semiconductor surface, lithographically patterning the layer of photoresist to leave a mask feature, etching the silicon surface not covered by the mask feature using SF6 for a first period, and etching portions of the mask feature using an oxygen plasma for a second period. The first period may be about 3 seconds and the second period may be about 3 seconds, wherein the first period of SF6 etching and the second period of oxygen etching comprise an etching cycle.

Each etch cycle may form a discrete, substantially orthogonal stepped surface, and wherein a plurality of etching cycles forms a plurality of substantially orthogonal stepped surfaces. The plurality of cycles may include at least 10 etching cycles, and forms at least 10 substantially orthogonal stepped surfaces.

The curved contour may be defined by a continuous line intersecting the plurality of discrete, stepped surfaces. The contour may define an optical refractive or reflective beam shaping element. The beam shaping element may be a lens with a focal distance of less than about 1 mm.

The process may further include disposing an optical source emitting a beam of radiation on the semiconductor surface, and enclosing the optical source and the contour in a lid wafer to form a sealed optical package. Alternatively, the process may further include disposing an optical receiver receiving a beam of radiation on the semiconductor surface, and enclosing the optical source and the contour in a lid wafer to form a sealed optical package. The silicon DRIE process may use a gas mixture which has a ratio of SF6 to O₂ of about 0.1% to 95%. The SF6 and O₂ etches may be performed with a gas pressure of about 15 mtorr.

While various details have been described in conjunction with the exemplary implementations outlined above, various alternatives, modifications, variations, improvements, and/or substantial equivalents, whether known or that are or may be presently unforeseen, may become apparent upon reviewing the foregoing disclosure. Accordingly, the exemplary implementations set forth above, are intended to be illustrative, not limiting.

1. A contour formed in a semiconductor substrate, comprising:
a raised feature with a curved contour, wherein the curved contour comprises multiple discrete, substantially orthogonal stepped surfaces, wherein in the curved contour is defined by a continuous line intersecting the discrete, stepped surfaces.

2. The contour formed in the semiconductor surface of claim 1, wherein each stepped orthogonal surface comprises a rise and a run, wherein the rise is orthogonal to the run, and wherein the rise is substantially equal to the run.

3. The contour formed in the semiconductor surface of claim 1, wherein each stepped orthogonal surface comprises a rise and a run, wherein the rise is orthogonal to the run, and wherein the rise is substantially twice the run.

4. The contour formed in the semiconductor surface of claim 1, wherein each stepped orthogonal surface comprises a rise and a run, wherein the rise is orthogonal to the run, and wherein the run is substantially twice the rise.

5. The contour formed in the semiconductor surface of claim 1, wherein each stepped orthogonal surface comprises a rise and a run, wherein the rise is orthogonal to the run, and wherein each stepped orthogonal surface has a lateral extent less than about about 100 nm.

6. The contour formed in the semiconductor surface of claim 1, wherein each stepped surface comprises a rise and a run, wherein the rise is orthogonal to the run, and the ratio of rise to run varies across the contour from about 0.1 to about 10.

7. The contour formed in the semiconductor surface of claim 1, wherein the contour defines an optical refractive or reflective beam shaping element.

8. The contour formed in the semiconductor surface of claim 7, wherein the beam shaping element is a lens with a focal distance of less than about 50 microns.

9. A microfabricated optical device, comprising:
an optical source emitting a beam of radiation; and
the contour of claim 1, wherein the contour shapes the beam or radiation by refraction or reflection at the contour.

10. A microfabricated optical device, comprising:
an optical source receiving a beam of optical radiation; and
the contour of claim 1, wherein the contour shapes the beam or radiation by refraction or reflection at the contour.

11. A process for making a contour on a semiconductor surface,
comprising:
depositing a layer of photoresist on the semiconductor surface;
lithographically patterning the layer of photoresist to leave a mask feature;
etching the silicon surface not covered by the mask feature using SF6 for a first period; and
etching portions of the mask feature using an oxygen plasma for a second period.

12. The process of claim 11, wherein the first period is about 3 seconds and the second period is about 3 seconds, wherein the first period of SF6 etching and the second period of oxygen etching comprises an etching cycle.

13. The process of claim 12, wherein each etch cycle forms a discrete, substantially orthogonal stepped surface, and wherein a plurality of etching cycles forms a plurality of substantially orthogonal stepped surfaces.

14. The process of claim 13, wherein the plurality comprises at least 10 etching cycles, and forms at least 10 substantially orthogonal stepped surfaces.

15. The process of claim 13, wherein in the curved contour is defined by a continuous line intersecting the plurality of discrete, stepped surfaces.

16. The process of claim 15, wherein the contour defines an optical refractive or reflective beam shaping element.

17. The process of claim 15, wherein the beam shaping element is a lens with a focal distance of less than about 50 microns.

18. The process of claim 15, further comprising:
disposing an optical source emitting a beam of radiation on the semiconductor surface; and
enclosing the optical source and the contour in a lid wafer to form a sealed optical package.

19. The process of claim 15, further comprising:
disposing an optical receiver receiving a beam of radiation on the semiconductor surface; and
enclosing the optical source and the contour in a lid wafer to form a sealed optical package.

20. The process of claim 11, wherein the SF6 and O₂ etches are performed with a gas pressure of about 15 mtorr.
